(19) United States
(12) Patent Application Publication
(10) Pub. No.: US 2012/0049173 A1
(43) Pub. Date: Mar. 1, 2012

(54) Organic Field Effect Transistor with Block Copolymer Layer

(75) Inventors: Jung-Wei CHENG, Taipei (TW); Jeng-Rong HO, Taipei City (TW); Chien-Chao TSIANG, Chia-Yi (TW); Cheng-Yi CHIANG, Chia-Yi (TW); Yu-Wei TSENG, Chia-Yi (TW); Ting-Ray CHEN, Chia-Yi (TW); Chi-Horng CHIEN, Chia-Yi (TW)

(73) Assignee: NATIONAL CHUNG CHENG UNIVERSITY, CHIA-YI (TW)

(21) Appl. No.: 13/217,260

(22) Filed: Aug. 25, 2011

(30) Foreign Application Priority Data
Sep. 1, 2010 (TW) 099129541

(51) Int. Cl. H01L 51/10

(52) U.S. Cl. 257/40; 257/E51.005

(57) ABSTRACT

An organic field effect transistor (OFET) having a block copolymer (BCP) layer is provided. The OFET includes a gate, an optional dielectric layer, a BCP layer, an organic semiconductor layer, a drain, and a source. The BCP layer is formed between the dielectric layer and the organic semiconductor layer when the dielectric layer exists. Otherwise, the BCP layer is formed between the gate and the organic semiconductor layer when the dielectric layer does not exist. When being positioned between the gate and the organic semiconductor layer without the dielectric layer, the BCP layer also functions as a dielectric layer. Inclusion of the BCP layer enhances the electrical properties, such as the charge carrier mobility, of the OFET.

### RELATED APPLICATIONS

This application claims priority to Taiwan Patent Application Serial Number 099129541, filed on Sep. 1, 2010. The entire disclosure of the application is hereby incorporated by reference herein.

### BACKGROUND

1. Technical Field

The present disclosure relates to a FET (Field Effect Transistor). More particularly, the present disclosure relates to an OFET (Organic Field Effect Transistor).

2. Description of Related Art

Organic semiconductor material has been well noticed due to its high flexibility and biocompatibility and the potential cost advantage of using a low-cost process to manufacture large-area devices. However, since the carrier mobility of a device formed from the organic semiconductor material is too low (referred to as an organic semiconductor device), the development of the organic semiconductor device applications is extremely restricted. Hence, there is a need with regard to how to promote the carrier mobility of the organic semiconductor device.

### SUMMARY

Hence, an aspect of the disclosure is to provide an organic field effect transistor (OFET) with a block copolymer layer for overcoming the problem of the conventional OFET of which the carrier mobility is too low.

According to one embodiment of the disclosure, an organic field effect transistor with a block copolymer layer is provided. The organic field effect transistor includes an organic semiconductor layer, a block copolymer layer, a drain, a source and a gate. The gate is located on a base, and the block copolymer layer is located on the gate and contacts the gate. The organic semiconductor layer is located on the block copolymer layer. The drain and the source are located at two terminals of the organic semiconductor layer respectively and contact the organic semiconductor layer. Therefore, the voltage applied on the gate induces a carrier channel between the drain and the source in the organic semiconductor layer. Furthermore, the alignment function of the block copolymer layer improves the arrangement of the molecules in the organic semiconductor layer, and thus the carrier mobility of the carrier channel is increased.

According to another embodiment of the disclosure, the organic field effect transistor further includes a dielectric layer located between the block copolymer layer and the gate. On the other hand, the block copolymer layer can be a microphase-separated structure randomly oriented or orderly oriented. In detail, the orientation of the aforementioned microphase-separated structure orderly oriented can be parallel or perpendicular to the direction of the electron flow between the drain and the source. It is worthy to be noted that the block copolymer layer can be formed from polystyrene-block-polymethylmethacrylate, and the organic semiconductor layer can be formed from poly(3-hexylthiophene). As to the structure, the drain and the source can be formed in a top contact configuration located on the organic semiconductor layer; or in a bottom contact configuration which is buried and covered by the organic semiconductor layer and contacts the block copolymer layer. Furthermore, the organic field effect transistors of the embodiments described above can also be designed to have a nano-size grooved surface that formed by etching the block copolymer layer.

In view of the foregoing, the organic field effect transistor with the block copolymer layer of the embodiments can enhance the carrier mobility of the carrier channel. As to the material selection, many kinds of material suitable for forming the block copolymer are available from the market to meet the requirements of the embodiments, and thus the technical skill in the disclosure is highly feasible.

### BRIEF DESCRIPTION OF THE DRAWINGS

FIG. 1 is a schematic view showing the structure of an OFET with a block copolymer layer according to one embodiment of the disclosure.

FIG. 2 is a schematic view showing the structure of the OFET shown in FIG. 1 with an additional dielectric layer.

FIG. 3 is a schematic view showing the structure of an OFET with a block copolymer layer according to another embodiment of the disclosure.

FIG. 4 is a schematic view showing the structure of the OFET shown in FIG. 1 with an additional dielectric layer.

FIG. 5 is an atomic microscope phase imaging of the PS-b-PMMA block copolymer thin film having randomly oriented structure.

FIG. 6 is a schematic view showing the manufacturing device for using the shearing stress to control the alignment direction of the oriented structure of the block copolymer.

FIG. 7 is an atomic microscope phase imaging of the PS-b-PMMA block copolymer thin film having orderly oriented structure.

FIG. 8 is a schematic view showing the manufacturing device for using the micro-contact printing technology to print the P3HT semiconductor layer on the block copolymer layer.

### DETAILED DESCRIPTION

The present disclosure is based on years of practical experience, long-term observation and efforts in academic research to improve the carrier mobility of the organic semiconductor units by controlling the micro-crystallization and the alignment of the molecules in the semiconductor material. Based on the academic research, new material, improved process and novel unit structure are three major ways to improve the mobility of the organic semiconductor units. Two main aspects of the improved process are described as follows. The first one is to improve and optimize the conventional process technologies by such as the spin coating with high boiling point solvent or the drop coating with solvent assistance. The second one is to develop specially designed interfaces between the dielectric layer and the semiconductor layer by such as selecting suitable dielectric materials, adding the self-assembled monolayer on the dielectric layer to modify the surface property, producing directional structures on the dielectric layer or applying alignment technologies on the surface of the dielectric layer. For instance, the alignment technology can be the polyimide (PI) dielectric layer alignment technology that is achieved by the flannel friction or the photo-alignment. The directional structure can be achieved by the SiO₂ dielectric layer having surface grooves or having hydrophobic areas and hydrophilic areas alternatively disposed on the surface.

Therefore, the disclosure provides a novel dielectric layer alignment technology using the block copolymer to self-organize a micro-phase separation surface structure. A block copolymer layer having nanometer scale grooves or nanometer scale hydrophobic areas and hydrophilic areas alternatively disposed on the surface can be achieved thereby, and thus the electrical properties such as the carrier mobility of the OFET can be improved effectively.

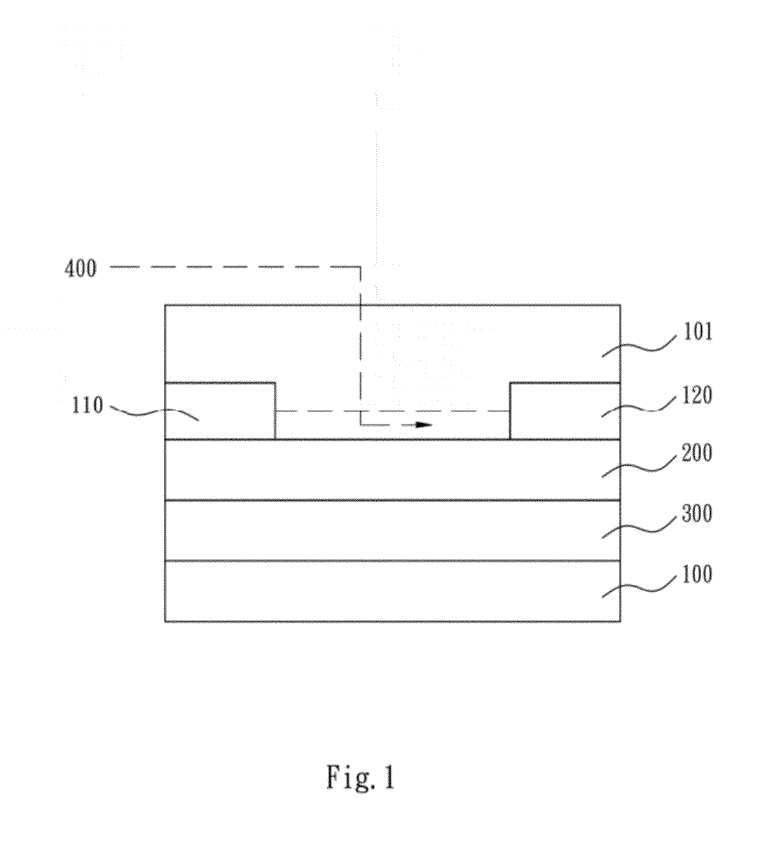

Referring to FIG. 1, FIG. 1 is a schematic view showing the structure of an OFET with a block copolymer layer according to one embodiment of the disclosure. In FIG. 1, the OFET includes a base 100, an organic semiconductor layer 101, a drain 110, a source 120, a block copolymer layer 200 and a gate 300. The gate 300 is located on the base 100, and the block copolymer layer 200 is located on the gate 300. The drain 110 and the source 120 are located respectively at two terminals of the organic semiconductor layer 200, and the organic semiconductor layer 101 is located on the block copolymer layer 200 and thus covers the drain 110 and the source 120.

In the embodiment, the drain 110 and the source 120 are embedded into the organic semiconductor layer 101, i.e. a bottom contact structure. When a voltage is applied on the gate 300 to induce a carrier channel 400, the existence of the block copolymer layer 200 can improve the carrier mobility of the carrier channel 400. On the other hand, since the block copolymer layer 200 also has the dielectric property, it can also be applied to replace the conventional dielectric layer.

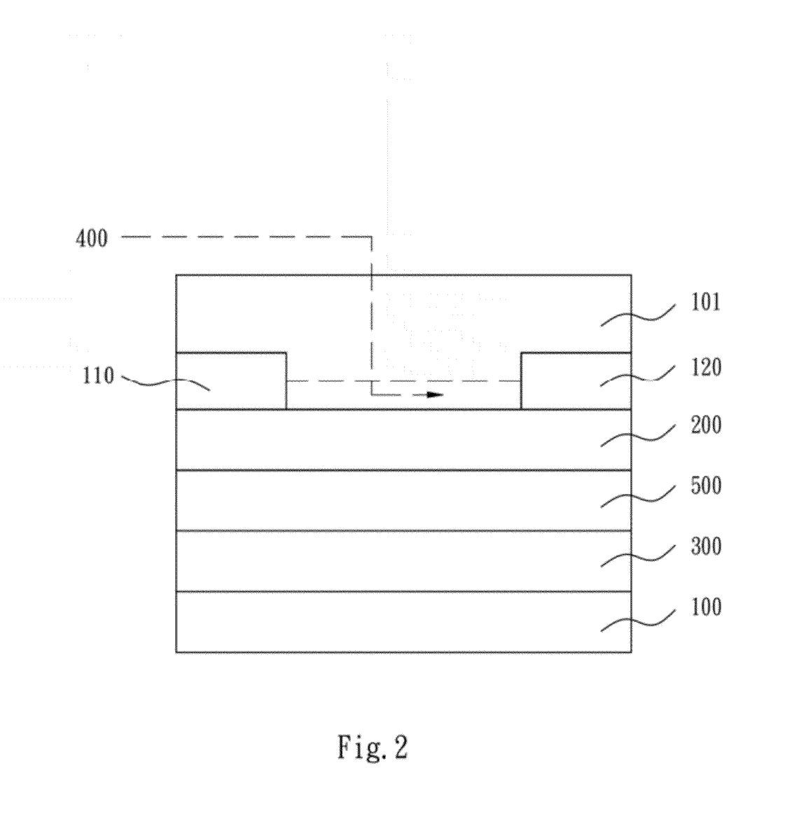

Referring to FIG. 2, FIG. 2 is a schematic view showing the structure of the OFET shown in FIG. 1 with an additional dielectric layer. The difference between FIG. 1 and FIG. 2 is that a dielectric layer 500 is arranged in the OFET of FIG. 2. In FIG. 2, the dielectric layer 500 is first formed on the gate 300, and then the block copolymer layer 200 is arranged on the dielectric layer 500. When the voltage is applied on the gate 300 to induce the carrier channel 400, the existence of the block copolymer layer 200 still can improve the carrier mobility of the carrier channel 400.

It is worthy to be noted that the dielectric layer 500 can be applied to adjust the entire electrical property of the OFET. For one instance, when the permittivity of the block copolymer layer 200 is not large enough, the existence of the dielectric layer 500 having high permittivity can be applied to increase the capacitance of the OFET and thus to promote the efficiency. For another instance, when the attachment between the block copolymer layer 200 and the gate 300 is not good enough, a proper dielectric layer 500 can be selected and applied to be an interface between the block copolymer layer 200 and the gate 300, wherein the gate 300 can be well attached to the dielectric layer 500, and the block copolymer layer 200 can be well attached to the dielectric layer 500.

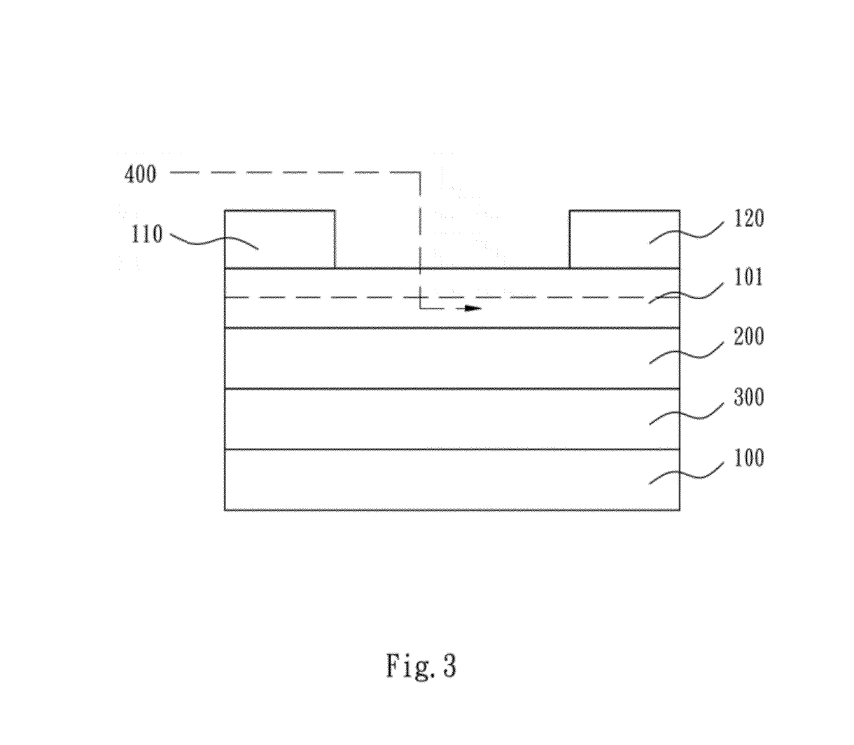

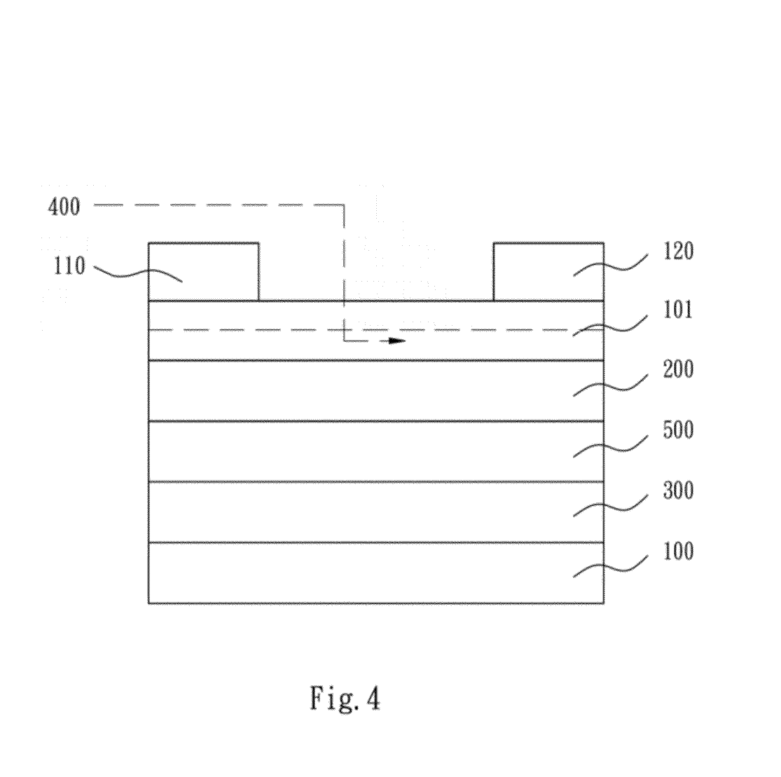

Referring to FIG. 3, FIG. 3 is a schematic view showing the structure of an OFET with a block copolymer layer according to another embodiment of the disclosure. The difference between FIG. 1 and FIG. 3 is that the drain 110 and the source 120 are not embedded into but located on the organic semiconductor layer 101, i.e. a top contact structure. Referring to FIG. 4, FIG. 4 is a schematic view showing the structure of the OFET shown in FIG. 3 with an additional dielectric layer. The difference between FIG. 4 and FIG. 3 is that a dielectric layer 500 is arranged in the OFET of FIG. 3.

Hereinafter, an example is provided to explain the improvement of the carrier mobility, wherein the OFET structure in FIG. 4 is taken as the example.

The selected materials of the layers of the OFET are described as follows:

1. The dielectric layer 500 is formed from SiO₂.

2. The block, copolymer layer 200 is formed from the polystyrene-block-polymethylmethacrylate (PS-b-PMMA) of which the molecular weight (Mn) is PS(46100)-b-PMMA(21000), purchased from the Polymer Source Company®.

3. The organic semiconductor layer 101 is formed from the poly(3-hexylthiophene), i.e. P3HT of which the molecular weight (Mw) is 47600 Da and the head-to-tail regioregularity is larger than 90%, purchased from the Aldrich Company®.

4. The gate 300, the drain 110 and the source 120 are 99.99% purity gold thin films plated by the thermal evaporation.

The manufacturing process of the OFET is described below:

First, a p-type silicon base having a SiO₂ layer with 300 nm in thickness is applied to be both the base 100 and the gate 300. The SiO₂ layer on the p-type silicon base is applied to be the dielectric layer 500. Second, a block copolymer layer 200 formed from the PS-b-PMMA described above is formed on the SiO₂ layer. The process of forming the block copolymer layer 200 on the SiO₂ layer will be introduced later. Third, an organic semiconductor layer 101 formed from the P3HT described above is transfer printed on the block copolymer layer 200 by using the micro-contact printing technology. The process of the micro-contact printing technology will also be introduced later. Fourth, the processed workpiece is baked in a vacuum oven under 100-120° C. (such as 110° C.) about 5-15 minutes (such as 10 minutes). Fifth, the positions of the drain 110 and the source 120 are defined by the shadow mask, and the drain 110 and the source 120 are formed by using a thermal evaporator to thermally evaporate gold thin films of 40 nanometers in thickness thereon. Therefore, the fabrication of the OFET depicted in FIG. 4 is completed.

It is worthy to be noted that the block copolymer layer 200 of the above example can be classified into two categories according to its self-separated micro-phases arrangement of the molecules. One category is a randomly oriented structure, and the other category includes an orderly oriented structure.

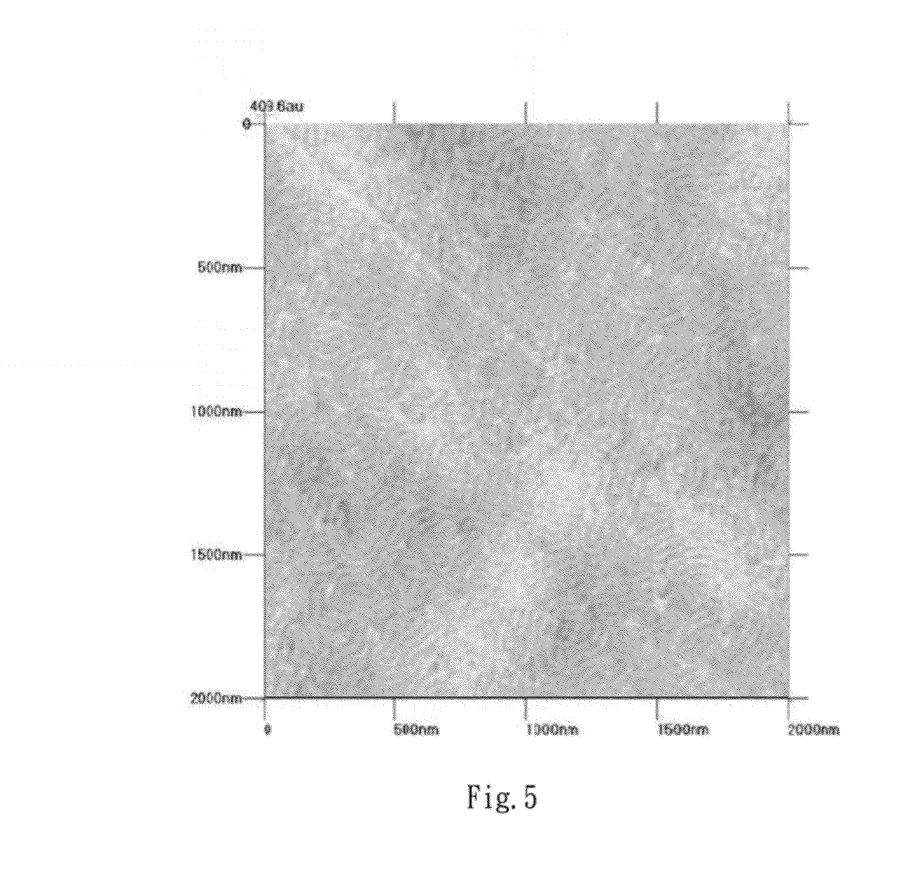

FIG. 5 is an atomic microscope phase imaging of the PS-b-PMMA block copolymer thin film having randomly oriented structure. In one example, the manufacturing method for the block copolymer layer having randomly oriented structure is described below: First, the PS-b-PMMA solution being 1.0 wt % dissolved in the toluene solvent is uniformly coated on the SiO₂ dielectric layer 500 by using the spin coater under 1800 RPM in 30 seconds, and thus the block copolymer layer 200 formed by the PS-b-PMMA solution is about 38 nanometers in thickness. Second, the processed workpiece described above is baked by a vacuum oven under 180° C. about 27 hours. Meanwhile, the surface of the PS-b-PMMA material is self-organized to be a randomly oriented micro-phase separation surface structure as being depicted in FIG. 5.

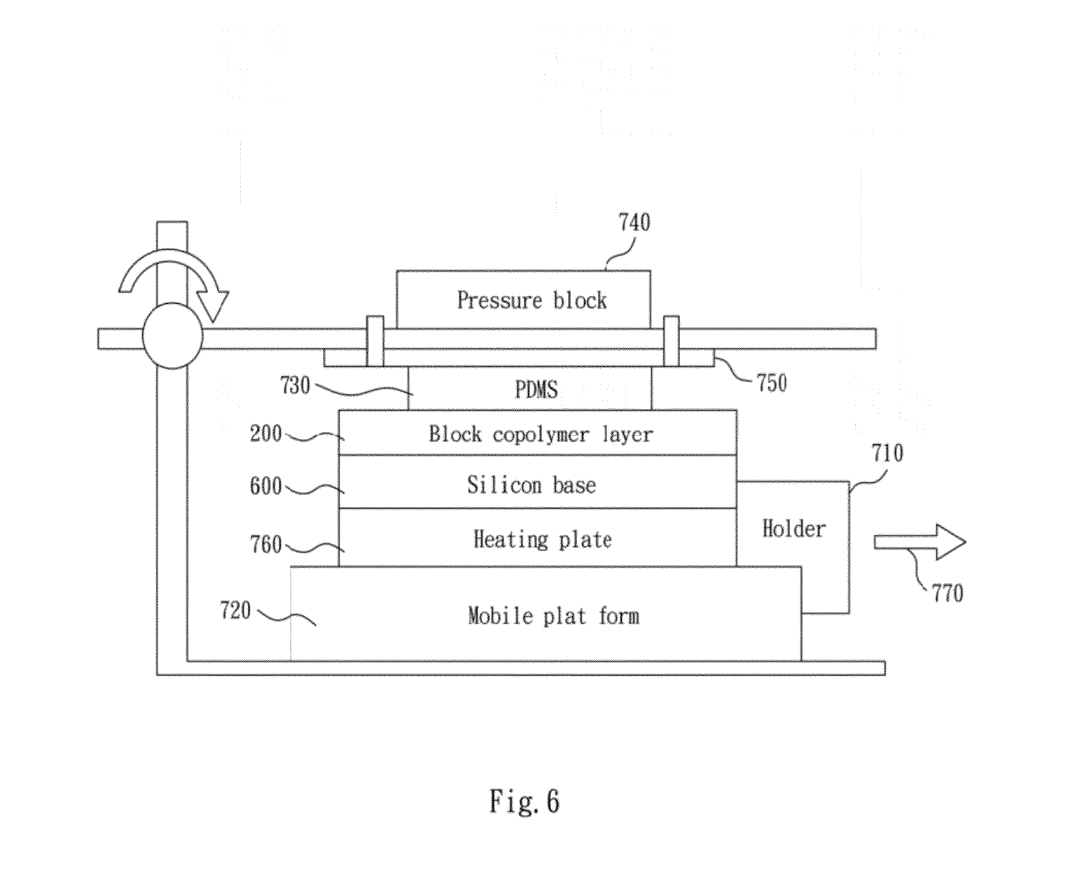

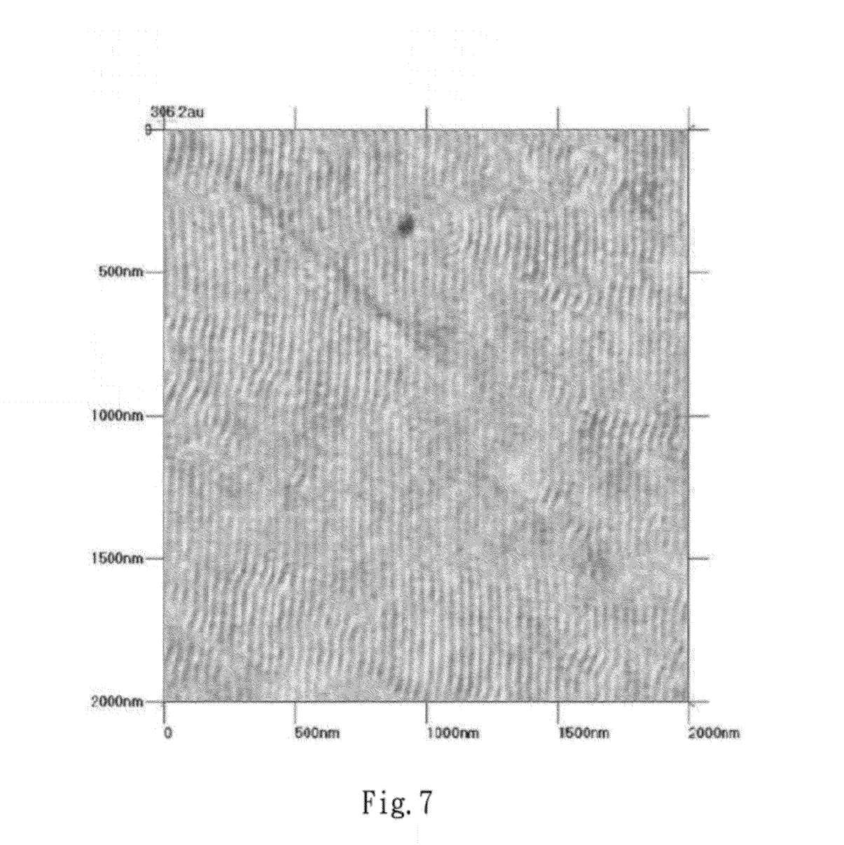

FIG. 6 is a schematic view showing the manufacturing device for using the shearing stress to control the alignment direction of the oriented structure of the block copolymer. FIG. 7 is an atomic microscope phase imaging of the PS-b-PMMA block copolymer thin film having orderly oriented structure. The block copolymer layer 200 having an orderly oriented structure is produced by the shearing stress controlling method described below. The first step and related parameters of manufacturing the block copolymer layer 200 having an orderly oriented structure is the same with that having a randomly oriented structure. And then, as being depicted in FIG. 6, the PS-b-PMMA solution is coated on a SiO₂ layer of a p-type silicon base 600. The p-type silicon base 600 is fixed on a heating plate 760 of a mobile platform 720 having micron resolution via a holder 710. A poly(dimethyl siloxane), i.e. PDMS, 730 is applied to press the PS-b-PMMA thin film, i.e. the block copolymer layer 200. Additionally, a pressure block 740 and a glass block 750 can be applied on the PDMS 730 for assistance. After the aforementioned steps are completed, the heating plate 760 provides a stable temperature, such as 160° C., that is greater than the glass transition temperature of the PS-b-PMMA, and the mobile platform 720 is driven to move along the direction 770 under 0.25 μm/s about 3 hours. Therefore, the microphase-separated structure of the PS-b-PMMA self-organizes along the direction of the shearing stress provided by the mobile platform 720. Finally, the PS-b-PMMA block copolymer layer 200 having orderly oriented structure is produced as shown in FIG. 7.

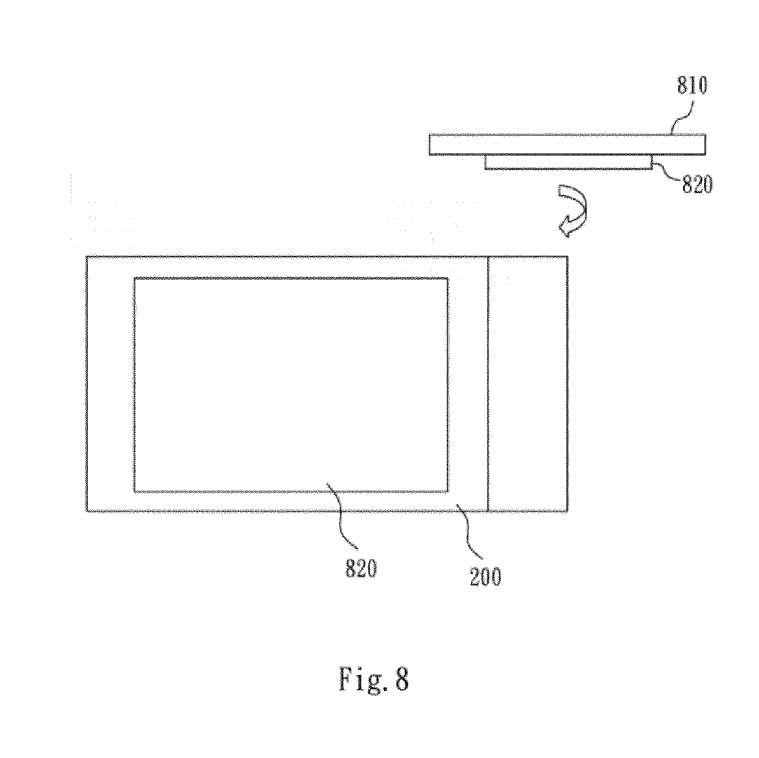

FIG. 8 is a schematic view showing the manufacturing device for using the micro-contact printing technology to print the P3HT semiconductor layer 101 on the block copolymer layer 200. The operating steps are described below: First, a PDMS stamp 810 is fixed on a slide. Second, a 1,2-dichlorobenzene (DCB) solvent is applied to clean the surface of the PDMS. Third, the cleaned PDMS stamp 810 is arranged on a spin coater, and the acetone is spread on the surface on the PDMS under 5000 RPM in one second for pre-wetting. Fourth, a P3HT thin film 820 is spin coated on the PDMS under 4000 RPM in 30 seconds. Fifth, the P3HT thin film 820 is transfer printed on the block copolymer layer 200 via the PDMS stamp 810 under about 70° C.

Table 1 is the electrical property comparing chart of the P3HT OFET produced by the example of the disclosure and the conventional OFET.

TABLE 1
the comparing Chart:

| Symbols | (a) | (b) | (c) | (d) |
|---|---|---|---|---|
| V_{T} (V) | 18.6 | −3.06 | −2.72 | −2.74 |
| Carrier mobility | 1.49 × 10⁻² | 0.73 × 10⁻² | 1.13 × 10⁻² | 0.70 × 10⁻² |
| (cm²V⁻¹s⁻¹) | | | | |
| Off current (A) | −7.39 × 10⁻⁷ | −2.59 × 10⁻⁹ | −3.27 × 10⁻⁹ | −2.61 × 10⁻⁹ |
| On current (A) | −7.11 × 10⁻⁶ | −1.32 × 10⁻⁶ | −2.07 × 10⁻⁶ | −1.28 × 10⁻⁶ |
| On−off current | 10 | 533 | 650 | 493 |
| ratio | | | | |

Symbol (a) represents a P3HT OFET without the block copolymer layer that configuration is similar with the structure in FIG. 4, but lacks the block copolymer layer 200.
Symbol (b) represents a P3HT OFET with a block copolymer layer having a randomly oriented structure.
Symbol (c) represents a P3HT OFET with a block copolymer layer having orderly oriented structure, and the orientation of the orderly oriented structure is parallel to the current I_{DS} between the drain and the source.
Symbol (d) represents a P3HT OFET with a block copolymer layer having orderly oriented structure, and the orientation of the orderly oriented structure is perpendicular to the current I_{DS} between the drain and the source.

Additionally, the carrier channels of the OFETs above are 50 μm in length and 1.0 mm in width. The OFETs are produced under an atmospheric environment, and the electrical properties are measured under the atmospheric environment.

In Table 1, the OFET represented by symbol (a) has extremely high off current and thus average on-off current ratio is merely 10. The root cause is that moisture in air performs a chemical doping reaction to the semiconductor material when there lacks the block copolymer layer 200 to cover it. Meanwhile, the threshold voltage V_{T} is an extremely high positive value, and thus the OFET cannot be completely closed, i.e. in off status, when the voltage on the gate is zero. Although the OFET has high carrier mobility, it cannot be regard as having better electrical property than the OFETs represented by symbols (b), (c) and (d). The reason is that extremely high threshold voltage and off current lead the OFET cannot be used as a normal electrical unit in the atmosphere environment. In other words, a FET having threshold voltage V_{T} about 18.6 V and off current almost about 1 mA is not a usable electrical unit under any SPEC.

On the other hand, the OFETs with block copolymer layer represented by symbols (b) (c) and (d) in Table 1 have usable electrical properties. Therefore, the OFETs of the disclosure can be produced under the atmosphere environment, and thus the manufacturing cost is decreased, and the yield is improved. Additionally, according to Table 1, the electrical properties such as the carrier mobility and the on-off current ratio can be further improved by controlling the order of the alignment direction of the oriented structure of the block copolymer layer 200.

For instance, when the microphase-separated structure of the block copolymer layer 200 self-organizes to be an orderly oriented structure as shown in FIG. 7, the orderly oriented structure can be controlled to parallel or perpendicular to an electron flowing direction between the drain 110 and the source 120. The carrier mobility of the OFET with block copolymer layer 200 which has the orderly oriented structure parallel to the current direction is 1.55 times than that has the randomly oriented structure.

Furthermore, the OFETs of the embodiments described above also can be designed to have a nano-size grooved surface that is formed by etching the block copolymer layer 200, and thus the conventional organic molecules crystalline arrangement technology using the submicron-size grooves is promoted to that using the nano-size grooves. Therefore, the crystalline arrangement of the organic semiconductor molecules is improved and the carrier mobility is increased thereby. The theory of the organic molecules crystalline arrangement technology using the submicron-size grooves can be referenced to the papers such as Ikeda, S., Saiki, K., Tsutsui, K., Edura, T., Wada, Y., Miyazoe, H., Terashima, K., Inaba, K., Mitsunaga, T., and Shimada, T., “Graphoepitaxy of sexithiophene on thermally oxidized silicon surface with artificial periodic grooves,” Appl. Phys. Lett. 88 (2006) 251905.

Briefly, one of the micro-phases on the block copolymer layer 200 can be removed by etching to form a surface with orderly nano-size grooves for improving the carrier mobility of the OFET. The etching steps are described below: First, the PMMA self-separated from the PS-b-PMMA is irradiated by the UV light. This step not only cures the PS micro-phase, but also breaks the molecular bonds of the PMMA micro-phase. Second, with broken bond, the PMMA micro-phase is disconnected from the PS micro-phase and is etched away by the acetic acid to form the nano-size grooves.

On the other hand, the conventional carrier mobility improving method by using the high boiling point solvent, such as Chang, J.-F., Sun, B., Breiby, D. W., Nielsen, M. M, Soiling, T. I., Giles, M., McCulloch, I., and Sirringhaus, H., “Enhanced mobility of poly(3-hexylthiophene) transistors by spin-coating from high-boiling-point solvents,” Chem. Mater., 2004, 16, 4772-4776, and Park, J., Lee, S., and Lee, H. H., “High-mobility polymer thin film transistors fabricated by solvent-assisted drop-casting,” Organic Electronics, 7, 256-260, 2006, also can be applied to the embodiments of the disclosure. Briefly, the method of applying the conventional technology in the embodiments includes the following steps. The organic semiconductor material is dissolved in the solvent having high boiling point, and thus is transfer printed on the block copolymer layer 200. After that, when the heating and alignment step described above corresponding to FIG. 6 is applied, the existence of the high boiling point solvent reduces the evaporation rate, and thus provides more time for the semiconductor material 101 to be self-organized on the block copolymer layer 200. The more complete the self-organized structure in the semiconductor material 101 is, the better carrier mobility the OFET has.

Additionally, the embodiments described above can be achieved by selecting many kinds of block copolymer materials to meet the requirements of different organic semiconductor materials, and thus the materials has many choices and are easy to be purchased. For instance, the PS-b-PMMA block copolymer material is selected to match the P3HT organic semiconductor material because the work of adhesion between the P3HT and the PS is greater than that between the P3HT and the PMMA. Therefore, if different organic semiconductor material other than the P3HT is applied, other kinds of block copolymer materials should be taken by considering the work of adhesion between the organic semiconductor material and the block copolymer material.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. An organic field effect transistor, comprising:
a gate located on a base;
a block copolymer layer which is located on the gate and contacts the gate;
an organic semiconductor layer located on the block copolymer layer; and
a drain and a source which are located respectively at two terminals of the organic semiconductor layer and contact the organic semiconductor layer.

2. The organic field effect transistor of claim 1, further comprising a dielectric layer located between the block copolymer layer and the gate.

3. The organic field effect transistor of claim 1, wherein the block copolymer layer is a microphase-separated block copolymer layer having a randomly oriented structure.

4. The organic field effect transistor of claim 1, wherein the block copolymer layer is a microphase-separated block copolymer layer having an orderly oriented structure.

5. The organic field effect transistor of claim 4, wherein an orientation of the orderly oriented structure is parallel to a direction of an electron flow between the drain and the source.

6. The organic field effect transistor of claim 4, wherein an orientation of the orderly oriented structure is perpendicular to a direction of an electron flow between the drain and the source.

7. The organic field effect transistor of claim 1, wherein the block, copolymer layer is formed from polystyrene-block-polymethylmethacrylate.

8. The organic field effect transistor of claim 1, wherein the organic semiconductor layer is formed from poly(3-hexylthiophene).

9. The organic field effect transistor of claim 1, wherein the drain and the source are located on the organic semiconductor layer.

10. The organic field effect transistor of claim 1, wherein the drain and the source are embedded into the organic semiconductor layer, so as to be covered by the organic semiconductor layer and contact the block copolymer layer.

11. The organic field effect transistor of claim 1, further comprising a nano-size grooved surface formed by etching the block copolymer layer.
